(19) United States
(12) Patent Application Publication
(10) Pub. No.: US 2021/0096467 A1
(43) Pub. Date: Apr. 1, 2021

(54) REDUCED FLOW RATE PROCESSING SYSTEM FOR FLEXOGRAPHIC PRINTING PLATE

(71) Applicant: MIRACLON CORPORATION, Oakdale, MN (US)

(72) Inventors: David Aviel, Minneapolis, MN (US); Fredrick Charles Mellema, Oakdale, MN (US); Andrew R. Williams, Buffalo, MN (US)

(73) Assignee: MIRACLON CORPORATION, Oakdale, MN (US)

(21) Appl. No.: 17/120,591

(22) Filed: Dec. 14, 2020

Related U.S. Application Data
(63) Continuation of application No. 15/861,781, filed on Jan. 4, 2018.

(51) Int. Cl. G03F 7/32; G03F 7/40; G03F 7/30

(52) U.S. Cl. CPC G03F 7/322; G03F 7/405; G03F 7/3071; G03F 7/203; G03F 7/3092; G03F 7/3042; G03F 7/30; G03F 7/3057

(57) ABSTRACT

A processing system includes a processing unit that processes the flexographic printing plate with a processing liquid. The processing unit includes a hollow tube having a length extending across a cross-track dimension of the flexographic printing plate. A processing liquid supply system supplies pressurized processing liquid into an interior of the hollow tube. A plurality of pressure-compensating emitters is distributed along the length of the tube which deliver processing liquid onto a surface of the flexographic printing plate, wherein processing liquid flows from the interior of the hollow tube through the pressure-compensating emitters at a controlled flow rate.

### CROSS-REFERENCE TO RELATED APPLICATIONS

This patent application is a continuation of U.S. patent application Ser. No. 15/861,781 filed Jan. 4, 2018, which application is incorporated herein by specific reference in its entirety.

Additionally, cross-reference is made to commonly assigned, co-pending U.S. patent application Ser. No. 15/196,122, entitled: “Aqueous processing method for flexographic printing plates”, by D. Swihart et al.; and to commonly assigned, co-pending U.S. patent application Ser. No. 15/196,132, entitled: “Aqueous processing system for flexographic printing plates”, by D. Swihart et al., each of which is incorporated herein by reference.

### FIELD OF THE INVENTION

This invention pertains to the field of flexographic printing, and more particularly to an aqueous processing method for flexographic printing plates.

### BACKGROUND OF THE INVENTION

Relief printing plates, such as flexographic plates, falls into two main categories: (1) those that are processed using aqueous solutions to remove unexposed photopolymer, and (2) those that need to be processed using some other chemical solvent. In recent years, flexographic printing plates using an aqueous-processable photopolymer are gaining more market interest because of their environmentally-friendly characteristics. They have the additional advantage that they can reduce organic solvent exposure at the workplace. Aqueous-processable printing plates are sometimes referred to as aqueous-washable printing plates because the processing typically involves washing off the unexposed photopolymer.

There are also two main types of aqueous-processable flexographic printing plates: (1) those that are processable by dissolution of the photopolymer using a strong alkaline solution (i.e., having a pH >11), and (2) those that are processable by dispersion of the photopolymer using a processing solution including a dispersing agent (typically having a pH<11).

Aqueous-processable flexographic printing plates may be processed (i.e., “washed”) by a number of methods. For example, U.S. Pat. No. 5,124,736 (Yamamoto et al.), entitled “Process and apparatus for developing photopolymer plate,” describe systems which form the relief by spraying processing solution (i.e., “washout solution”) under pressure onto the printing plate, and systems which form the relief by rubbing a brush against the printing plate in the presence of the processing solution, thereby dissolving the unexposed portions in the processing solution. Yamamoto et al., describe a system in which processing solution is filtered and recirculated to the plate processor after a full batch of platemaking.

As noted by U.S. Pat. No. 6,247,856 (Shibano et al.), entitled “Developing system of photosensitive resin plates and apparatus used therein,” photopolymer (i.e., resin) can build up in the used processing solution after processing a number of printing plates. This can cause various problems, such as decreasing the speed of development, and the dispersed resin forming scum which adheres to the plates and the brush. This can require frequent disposal of the used processing solution and preparation of a fresh processing solution. Shibano et al. discloses the addition of fresh processing solution to a processing unit, while removing part of the resin-containing processing solution to keep the resin content of the processing solution substantially constant.

In order to remove debris that becomes attached to the surface of the printing plate, a rinsing station can be employed after the main plate processing step. U.S. Patent Application Publication No. 2009/0013888 (Danon), entitled “Methods and means relating to photopolymer printing plates,” discloses processing a printing plate using a processing solution, followed by rinsing with water in a rinsing station. Used processing solution is recycled back to the processor after filtration. Waste water from the rinsing station may also be recycled back to the processor after filtration.

U.S. Pat. No. 5,828,923 (Harabin et al.), entitled “Apparatus and method for processing water wash photopolymer solution,” disclose directing used processing solution into a holding tank, and adding a coagulant to coagulate the solid content for disposal.

European Patent 0586470B1 (Danon), entitled “Preparation of photopolymerised elastomeric printing plates” disclose a processing system including (a) a wash-out section where unexposed areas of the plate are removed; (b) a rinse section; (c) an excess water-removing section; (d) a light-finishing section where the plate is exposed by UV light to reduce the stickiness of the plate surface; and (e) a drying section.

European patent 0586483B1 (Danon), entitled “Method and Apparatus for washing-out printing plates,” discloses a system for processing printing plates where processing solution is directed through a spray bar along downwardly directed bristles of a washout brush.

It has been found that even when utilizing a plate processor that includes a rinse operation, such as that disclosed in the aforementioned U.S. Patent Application Publication No. 2009/0013888, there can still be significant problems with plate defects after the production of only a few plates. The occurrence of plate defects is particularly problematic with the increasingly popular photopolymer plates with include micro-texture on the raised plate surface (i.e., the printing surface). As discussed in U.S. Pat. No. 8,399,177 (Stolt et al.), entitled “Enhanced printing plate,” the micro-texture is beneficial to enhance print density and uniformity. In such cases, the debris particles tend to accumulate on the micro-texture surface of the printing plate, which results in unacceptable print defects after processing a small number of printing plates.

It is desirable to minimize the amount of processing solution required to process the printing plates in order to reduce costs and reduce the volume of used solution that must be disposed of. However, prior art processing systems have been found to require relatively high flow rates of processing solution in order to maintain a high quality level. There remains a need for an improved processing system for processing flexographic printing plates that requires lower flow rates of processing solution.

### SUMMARY OF THE INVENTION

The present invention represents a processing system for processing a flexographic printing plate which moves along a processing path in an in-track direction, including:

a processing unit that processes the flexographic printing plate with a processing liquid including:
a hollow tube having a length extending across a cross-track dimension of the flexographic printing plate;
a processing liquid supply system for supplying pressurized processing liquid into an interior of the hollow tube; and
a plurality of pressure-compensating emitters distributed along the length of the tube which deliver processing liquid onto a surface of the flexographic printing plate, wherein processing liquid flows from the interior of the hollow tube through the pressure-compensating emitters at a controlled flow rate.

This invention has the advantage that a uniform flow of processing solution can be obtained across the width of the printing plate at a reduced total flow rate.

It has the further advantage that printing plates can be processed using a lower volume of processing solution which reduces processing solution costs and processing solution disposal costs.

### BRIEF DESCRIPTION OF THE DRAWINGS

FIGS. 1A-1D illustrate the steps involved with forming a flexographic printing plate according to an exemplary process;

FIG. 2 shows a schematic diagram of a system for processing a photosensitive flexographic printing plate;

FIG. 3 illustrates a conventional processing unit incorporating a trough-based liquid distribution system;

FIG. 4 shows additional details of the trough of FIG. 3;

FIG. 5 shows an improved processing unit incorporating a plurality of pressure-compensating emitters according to an exemplary embodiment;

FIG. 6 shows additional details of the processing unit of FIG. 5; and

FIG. 7 illustrates an alternate embodiment incorporating a brush which is moved laterally.

It is to be understood that the attached drawings are for purposes of illustrating the concepts of the invention and may not be to scale. Identical reference numerals have been used, where possible, to designate identical features that are common to the figures.

### DETAILED DESCRIPTION OF THE INVENTION

The invention is inclusive of combinations of the embodiments described herein. References to “a particular embodiment” and the like refer to features that are present in at least one embodiment of the invention. Separate references to “an embodiment” or “particular embodiments” or the like do not necessarily refer to the same embodiment or embodiments; however, such embodiments are not mutually exclusive, unless so indicated or as are readily apparent to one of skill in the art. The use of singular or plural in referring to the “method” or “methods” and the like is not limiting. It should be noted that, unless otherwise explicitly noted or required by context, the word “or” is used in this disclosure in a non-exclusive sense.

In accordance with the present invention, flexographic printing plates are formed by applying an aqueous processing solution to photosensitive flexographic printing plate precursors having latent images formed in an aqueous-processable photopolymer. In an exemplary embodiment, the photosensitive flexographic printing plates are similar to those described in U.S. Pat. No. 8,492,449 No. (Inoue et al.), entitled “Photosensitive resin composition, printing plate precursor and flexographic printing plate.” However, the described processing system and method is applicable to other types of aqueous-processable printing plates, including other types of aqueous-processable relief printing plates (e.g., letterpress printing plates).

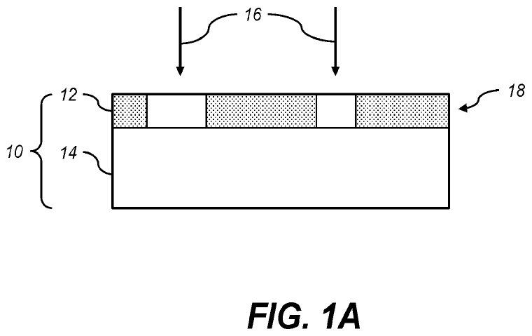

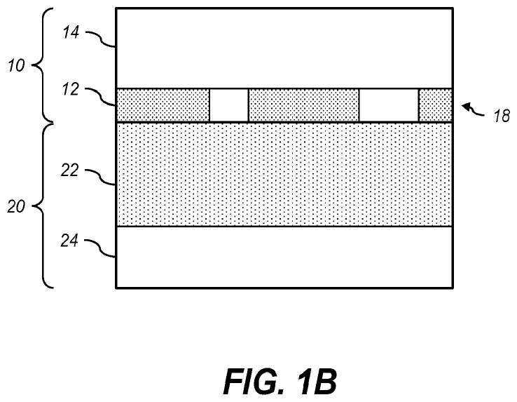

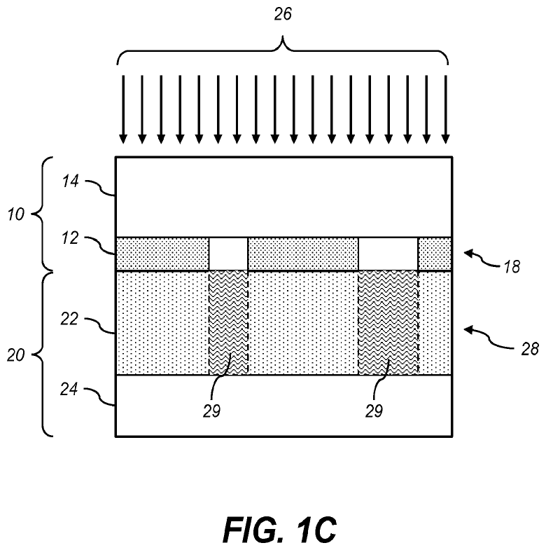

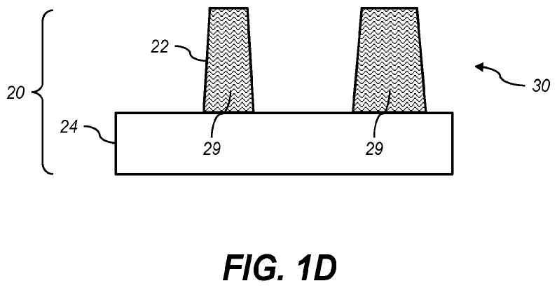

Before processing, a latent image is formed on the photosensitive flexographic printing plate using any appropriate method known in the art. In an exemplary embodiment, the latent image is formed using a mask image as described in commonly-assigned U.S. Pat. No. 9,250,527 (Kidnie), entitled “Mask forming imageable material and use,” which is incorporated herein by reference. This method is illustrated in FIGS. 1A-1D.

FIG. 1A illustrates a mask material 10, which includes a mask layer 12 on a substrate 14. In an exemplary embodiment, the mask material 10 is the commercially-available Kodak Flexcel NX Thermal Imaging Layer material. Further information about such mask materials 10 can be found in the aforementioned U.S. Pat. No. 9,250,527. The mask layer 12 is opaque to the radiation that will be used to expose the photosensitive flexographic printing plate (e.g., to UV radiation). The mask material 10 is exposed to radiation 16 in an image-wise fashion to form a mask image 18 in the mask layer 12. The mask image 18 will typically include patterns of halftone dots, lines, text and solid areas (with or without micro-surface patterning) according to the image content to be printed. In an exemplary embodiment, the radiation 16 is provided by a commercially-available Kodak Trendsetter NX Imager, which uses an infrared laser to ablate portions of the mask layer 12 where it is desired to produce raised features on the flexographic printing plate.

As illustrated in FIG. 1B, the mask material 10 is now laminated to a photosensitive printing plate 20. The photosensitive printing plate 20 includes a photosensitive photopolymer layer 22 over a substrate 24. The mask material 10 is laminated such that the mask layer 12 having the mask image 18 faces the photopolymer layer 22. In an exemplary embodiment, the photosensitive printing plate 20 is of a type similar to those described in the aforementioned U.S. Pat. No. 8,492,449 (Inoue et al.) (except that no antiadhesive layer is included over the photopolymer layer), and the lamination is performed (after removing the cover film from the photosensitive printing plate 20) using a commercially-available Kodak Flexcel NX laminator so that the mask material 10 is in an intimate contact with the photopolymer layer 22 of the photosensitive printing plate 20.

In FIG. 1C, the laminated photosensitive printing plate 20 is exposed to radiation 26 to form a latent image 28 in the photopolymer layer 22. Various commercially available UV exposure devices may be used to perform this operation. In an exemplary embodiment, the radiation 26 is UV radiation supplied by a commercially-available Concept 302 EDLF system available from Mekrom Engineering. Where the mask image 18 has been ablated, the radiation 26 passes through the mask layer 12 and exposes the photopolymer layer 22, thereby cross-linking and hardening the photopolymers to provide a developable latent image 28 including cross-linked polymer regions 29. The UV exposure 26 can be provided at a wide range of temperatures from about room temperature up to 60 C. However, it has been found that UV radiation exposure performed at elevated temperatures in the range of 42 C-52° C. provides better final plate quality (e.g., improved minimum dot holding and better resolution of surface micro-textures).

After the latent image 28 has been formed, the mask material 10 is removed, and the photosensitive printing plate 20 is processed to provide a developed relief image 30 as illustrated in FIG. 1D. The processing operation (sometimes referred to as “developing the printing plate”) involves removing the unexposed portions of the photopolymer layer where were not hardened by the radiation 26 (FIG. 1C) leaving the cross-linked polymer regions 29. In accordance with the present invention, the photopolymer layer 22 is made of an aqueous-processable photopolymer so that the processing operation uses an aqueous processing solution (i.e., a water-based processing solution), typically including an active ingredient such as a dispersing agent. Aqueous processing solutions are generally preferred to processing solutions using other solvents (e.g., organic solvents) because of their environmentally-friendly characteristics.

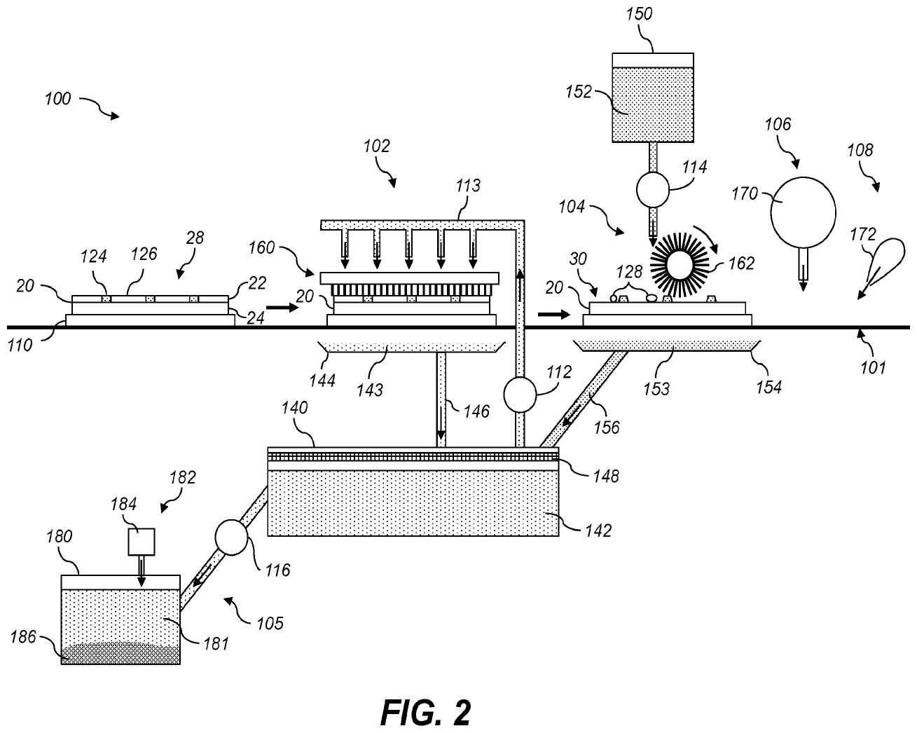

FIG. 2 shows a schematic diagram of an exemplary processing system 100 for processing an aqueous-processable photosensitive printing plate 20 in accordance with the present invention. In an exemplary embodiment, the photosensitive printing plate 20 is of a type similar to those described in the aforementioned U.S. Pat. No. 8,492,449 (Inoue et al.) (except that no antiadhesive layer is included over the photopolymer layer). However, other types of aqueous-processable printing plates can also be used.

In the exemplary arrangement of FIG. 2, the plate processing takes place as an “in-line process” where the photosensitive printing plate 20 proceeds through the processing system 100 along a processing path 101 where a series of processing operations are applied. In alternate embodiments, the plate processing can be performed as a “batch process”, where after the main plate processing, the plate moves in the reverse direction and the secondary processing takes place similar to the in-line process.

In an exemplary arrangement, the photosensitive printing plate 20 is mounted on a platen 110 as it is moved along the processing path 101. The input to the processing system 100 is a photosensitive printing plate 20 having a latent image 28 formed by exposing the photopolymer layer 22. The latent image 28 includes exposed portions 124 where the photopolymer layer 22 has been hardened by exposure to appropriate actinic radiation, and unexposed portions 126 where the photopolymer layer 22 remains soft and is to be removed from the substrate 24 during processing.

Main processing unit 102 is used to develop the latent image 28 into a relief image 30 by removing the unexposed portions 126 of the photopolymer layer 22 from the photosensitive printing plate 20. The main processing unit 102 can also referred to as a processing station or a development unit/station. The main processing unit 102 includes a pump 112 for drawing aqueous processing solution 142 from a processing solution tank 140 and directing it through a series of pipes 113 to bring the aqueous processing solution 142 into contact with the photosensitive printing plate 20.

The aqueous processing solution 142 includes a dispersing agent (i.e., “soaps”) to aid in the removal of the unexposed photopolymer. Any appropriate dispersing agent known in the art can be used in accordance with the present invention. Some examples of appropriate dispersing agents are discussed in U.S. Pat. No. 9,005,884 (Yawata et al.), entitled “Developer composition for printing plate, developer and method for manufacturing printing plate,” which is incorporated herein by reference. In one example, the dispersing agent is a salt of an fatty acid, preferably having an average carbon number in the range of 10-20. In another example, the dispersing agent is a sulfonate, such as an alkylbenze sulfonate having an average carbon number in the range of 8-16, or an −α-olefin sulfonate having an average carbon number in the range of 10-20. In a preferred embodiment, the aqueous processing solution 142 is heated to a predetermined value between 40 C to 60 C.

In a preferred configuration, the main processing unit 102 includes a mechanical cleaning system 160 to aid in removing the unexposed photopolymer from the photosensitive printing plate 20. The mechanical cleaning system 160 typically includes one or more brushes which contact the photopolymer layer 22 of photosensitive printing plate 20 while it is in contact with the aqueous processing solution 142. The brushes are preferably moved relative to the photosensitive printing plate 20, for example in a side-to-side motion or an orbital motion.

Various brush configurations can be used in accordance with the present invention. For example, the brushes can be downward facing as shown in FIG. 2. Examples of downward-facing brush configuration are shown in European Patent No. 0586483B1, European Patent No. 0586470B1, and U.S. Pat. No. 8,444,333 (Suzuki et al.), each of which is incorporated herein by reference. Alternatively, the brushes can be upward facing such as in the configurations described in U.S. Pat. No. 5,124,736 (Yamamoto et al.) and U.S. Pat. No. 6,247,856 (Shibano et al.), each of which are incorporated herein by reference.

A collection system 144 is used to collect the used aqueous processing solution 143 and return it to the processing solution tank 140 through a conduit 146. The used aqueous processing solution 143 will contain the photopolymer that was removed from the unexposed portions 126 of the photopolymer layer 22. The used aqueous processing solution 143 is preferably passed through a filter 148 to remove larger particles of the removed photopolymer. In an exemplary embodiment, the filter 148 is a coarse fabric-type filter material having a pore size of about 100 μm similar to that described in WO 2014/114900 A2 (Danon), entitled “Processing waste washout liquid.” In some configurations, the filter 148 is supplied in a roll format, and the filter material is advanced during operation of the processing system 100 to provide fresh filter material. The used filter material containing the photopolymer particles is collected on a take-up roll.

The main processing unit 102 removes the majority of the unexposed photopolymer from the photosensitive printing plate 20 to provide the relief image 30. However, it has been observed that debris 128 is typically present on the surface of the relief image 30. The debris 128 is primarily made up of residual particles of photopolymer that were not washed off the surface of the photosensitive printing plate 20.

A secondary processing unit 104 is used to wash the developed relief image 30 with a secondary aqueous processing solution 152 supplied from a supply tank 150 to remove the remaining debris 128. The secondary processing unit 104 can also be referred to as a secondary processing station, a secondary developing unit/station or a washing unit/station. Preferably, a pump 114 is used to direct the secondary aqueous processing solution 152 onto the photosensitive printing plate 20 under pressure, bringing it into contact with the developed relief image 30.

In a preferred embodiment, an optional mechanical cleaning system 162, such as a rotating brush, is used to enhance the performance of the secondary processing unit 104 by supplementing the washing action of the secondary aqueous processing solution 152 with mechanical cleaning.

Some prior art systems, utilize a water rinsing operation to clean the surface of the developed relief image 30. However, rather than being a simple water rinse, the secondary aqueous processing solution 152 used in the secondary processing unit 104 of the present invention includes an active ingredient (i.e., a dispersing agent) to aid in the removal of the debris 128. The secondary aqueous processing solution 152 is unused, meaning that it has not previously been used to process a photosensitive printing plate 20 and therefore contains no photopolymer. It has been found that this substantially improves the effectiveness of removing the debris 128. In a preferred embodiment the secondary aqueous processing solution temperature is between 40 C-55 C.

Any appropriate dispersing agent can be used in the secondary aqueous processing solution 152 such as those that were discussed earlier relative to the aqueous processing solution 142. In an exemplary configuration, the dispersing agent in the secondary aqueous processing solution 152 is the same as the dispersing agent used in the aqueous processing solution 142 used in the main processing unit 102. In other configurations, the dispersing agent in the secondary aqueous processing solution 152 can be different than the dispersing agent used in the aqueous processing solution 142.

In an exemplary configuration, the concentration of the dispersing agent in the secondary aqueous processing solution 152 is the same as the initial concentration of the dispersing agent in the aqueous processing solution 142 used in the main processing unit 102. In other configurations, the concentration of the dispersing agent in the secondary aqueous processing solution 152 can be greater than (or less than) than the concentration of the dispersing agent in the aqueous processing solution 142.

A collection system 154 collects the used secondary aqueous processing solution 153 from the secondary processing unit 104 and directs it into the processing solution tank 140 through a conduit 156. This has the advantage that it replenishes the used aqueous processing solution 143 that can contain large amounts of photopolymer with the fresher used secondary aqueous processing solution 153 from the secondary processing unit 104 which will contain only small amounts of photopolymer (i.e., the removed debris 128).

A processing solution removal system 105 is used to remove aqueous processing solution 142 from the processing solution tank 140 and direct it into a holding tank 180. This enables the volume of the aqueous processing solution 142 in the processing solution tank 140 to be maintained below a predefined maximum volume as the used secondary aqueous processing solution 153 is added to the processing solution tank 140. In an exemplary configuration, the processing solution removal system 105 uses a pump 116 to pump the aqueous processing solution 142 from the processing solution tank 140 into the holding tank 180. Preferably, the amount of aqueous processing solution 142 removed from the processing solution tank 140 is equal to the amount of used secondary aqueous processing solution 153 that is added to the processing solution tank 140 so that the total volume of aqueous processing solution 142 in the processing solution tank 140 remains approximately constant. In some embodiments, the pump 116 is operated on a predefined schedule (e.g., after processing each photosensitive printing plate 20). In other embodiments, the pump 116 can be operated when it is detected that the volume of aqueous processing solution 142 in the processing solution tank 140 is detected to exceed a predefined threshold.

The removal of the aqueous processing solution 142 by the processing solution removal system 105 in combination with the addition of the used secondary aqueous processing solution 153 from the secondary processing unit 104 enables the concentration of photopolymer in the aqueous processing solution 142 in the processing solution tank 140 to be maintained below a predefined maximum photopolymer concentration. Without this replenishment process, it has been found that the concentration of the photopolymer in the aqueous processing solution 142 in the processing solution tank 140 quickly builds up to an unacceptable level which detrimentally effects the performance of the processing system 100 after only processing a few (e.g., five or less) photosensitive printing plates 20. However, using the described replenishment process it has been found that acceptable performance can be maintained even after processing a large number (e.g., more than 50) photosensitive printing plates 20.

The aqueous processing solution 142 operates optimally within a defined pH range. The presence of the photopolymer in the used aqueous processing solution 143 can change the pH of the solution thereby reducing its effectiveness. The described process including the removal of the aqueous processing solution 142 by the processing solution removal system 105 in combination with the addition of the used secondary aqueous processing solution 153 from the secondary processing unit 104 enables the pH of the aqueous processing solution 142 in the processing solution tank 140 to be maintained within a predefined acceptable pH range for processing a larger number of photosensitive printing plates 20.

In the exemplary processing system 100, after the photosensitive printing plate 20 has been processed by the secondary processing unit 104, it is rinsed using a rinsing unit 106 which directs a stream of water 170 onto the surface of the developed relief image 30. This water rinsing is used to remove any residual processing solution from the surface of the photosensitive printing plate 20. The photosensitive printing plate 20 is then dried using a drying unit 108. In an exemplary configuration, the drying unit 108 uses an air knife 172 to direct a stream of air onto the surface of the developed relief image 30.

At some point it is necessary to discard the waste processing solution 181 collected in the holding tank 180. In an exemplary configuration, a coagulant supply system 182 can be used to add an appropriate coagulant 184 to the waste processing solution 181 to coagulate the polymer in the waste processing solution 181. The resulting solid coagulated polymer 186 can then be removed from the solution and discarded in an appropriate manner. The remaining waste processing solution 181 can then be disposed of in most locations without any significant environmental concerns. Examples of coagulants 184 that can be used to produce the coagulated polymer 186 include Bentonite clay (such as commercially available RM-10 from Cetco), Alum (potassium aluminum sulphate), aluminum sulphate, strong acids (such as hydrochloric acid), ferric chlorides, and many other chemicals commonly used in waste water treatment. Bentonite Clay RM-10 is particularly preferred.

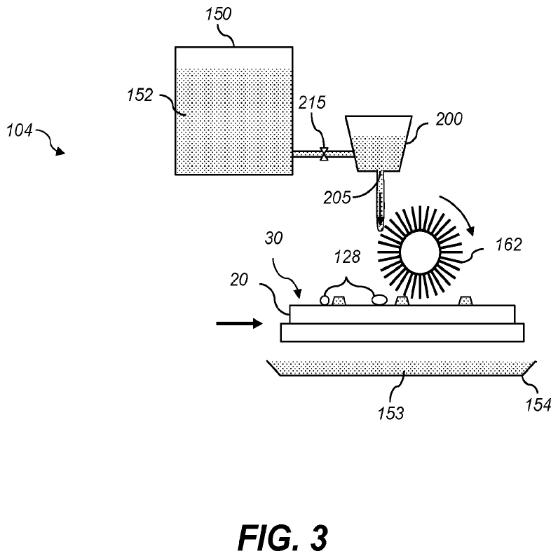

In some prior art processing systems, the secondary processing unit 104 includes a fluid distribution trough 200 which distributes the processing solution 152 across the width of the printing plate 20 as illustrated in FIG. 3. Distribution of the processing solution 152 can be implemented by releasing processing solution 152 from a supply tank which may be at or above atmospheric pressure into the trough 200. In other configurations, rather than using a supply tank, a dosing pump (such as the Dosatron D14MZ10 available from Dosatron International of Clearwater, Fla.) can be used to mix the processing agent directly into a pressurized water supply to provide the processing solution 152. The total flow rate (i.e., the flow amount per unit of time) is restricted by an orifice such as a valve 215 (e.g., a flow control valve or a needle valve). The trough 200 is equipped with small holes 205 at its bottom. The processing solution 152 drips through the holes 205 by gravity force and flows onto the printing plate 20. In an exemplary configuration, a mechanical cleaning system 162 such as a rotating brush is used to assist in removal of debris 128 from the printing plate 20.

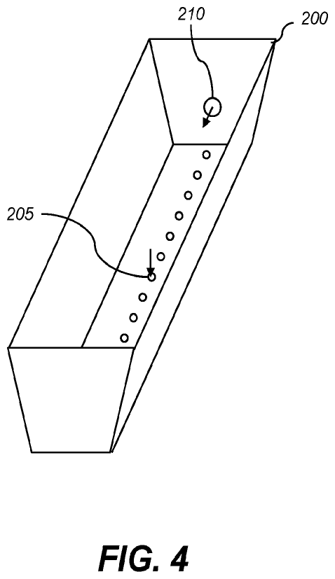

FIG. 4 shows additional details of the trough 200. A plurality of holes 205 are distributed along a length of the trough 200 to provide processing solution 152 across a cross-track width of the printing plate 20 (FIG. 3). The processing solution 152 flows into the trough 200 through an inlet 210 and is distributed along the length of the trough 200 at atmospheric pressure by gravity force where it drips through the holes 205. A disadvantage of this design is that as the total flow rate is decreased to reduce waste, differences in the drip rate of the processing solution 152 from the holes 205 become significant. As a result, liquid discharge across the printing plate 20 becomes uneven to a level that causes defects. In some cases, the holes 205 farthest from the inlet 210 may completely stop dripping. Further, as total flow rate is decreased, any lack of levelness of the distributing trough 200 negatively impacts the evenness of drip rate through the holes 205. In some processing systems, a pipe having a series of holes is used rather than a trough 200. Since the pipe is supplied with processing solution at atmospheric pressure such configurations suffer from the same disadvantages that were just discussed.

Examples of processing systems that utilize a liquid distribution system similar to that shown in FIGS. 3-4 include water wash systems such as the Dantex DigiWash models DW2735, DW4835, DW4260 and solvent processing systems such as the Vianord EVO 5BP and the Glunz & Jense Concept 505 DW.

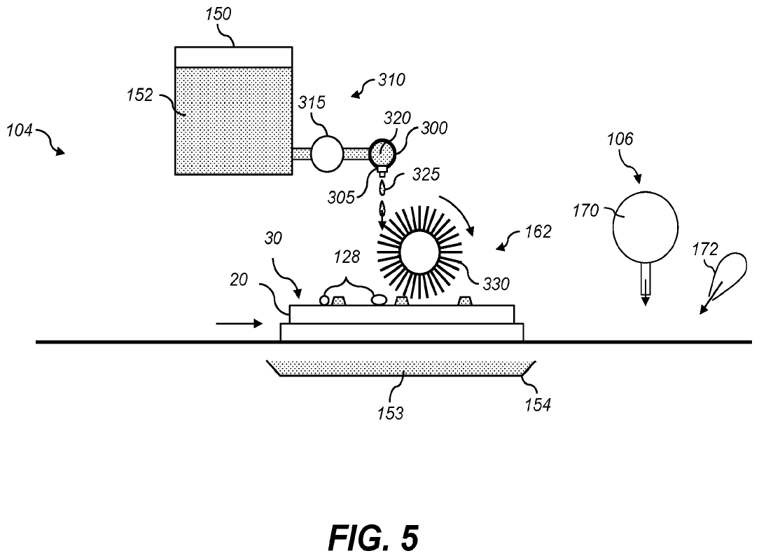

FIG. 5 illustrates an improved processing unit 104 that overcomes the disadvantages of the prior art configuration described relative to FIGS. 3-4. In the improved configuration, the trough 200 containing processing solution 152 at atmospheric pressure of FIG. 3 is replaced by a hollow tube 300 which is supplied with pressurized processing solution 320. The pressurized processing solution 320 is supplied to the interior of the hollow tube 300 by a processing liquid supply system 310. In an exemplary embodiment, the processing liquid supply system 310 includes a dosing pump 314, such as the Dosatron D14MZ10, which adds processing agent into a pressurized water supply. Typically, the pressurized water supply supplies water at pressures of 30-60 psi. A plurality of pressure-compensating emitters 305 are distributed along the length of the hollow tube 300. The pressurized processing solution 320 flows from the interior of the hollow tube through the pressure-compensating emitters 305 at a controlled flow rate to produce processing solution drips 325 which flow onto the printing plate 20. The pressure-compensating emitters 305 are manufactured to provide a specified dripping rate over a wide range of pressures in the hollow tube 320.

Pressure-compensating emitters are well-known in the field of drip irrigation systems and such components can be adapted for use in the present invention. Examples of pressure-compensating emitters are described in U.S. Pat. No. 4,281,798 to Lemelstrich entitled “Drip or trickle emitter;” U.S. Pat. No. 4,971,253 to Lazarus entitled “Pressure compensating emitters for drip irrigation systems;” U.S. Pat. No. 5,820,029 to Marans entitled “Drip irrigation emitter;” and U.S. Pat. No. 9,307,705 to Akritanakis, entitled “Pressure compensating drip irrigation emitter.” Pressure-compensating emitters 305 at a wide range of dripping rates are commercially available from a variety of suppliers including Rain Bird Corporation of Azusa, Calif.

As with the processing system 100 described relative to FIG. 2, a rinsing unit 106 can be used to rinse the printing plate 20 with water 170 after the processing unit 104 completes is processing operation, and an air knife 172 (i.e., a pressurized air system) can be used to blow any remaining liquid off the surface of the printing plate 20. In some embodiments, the rinsing unit 106 can also be equipped with a liquid supply system having a plurality of pressure-compensating emitters 305 distributed along the length of a hollow tube 300 as in processing unit 104.

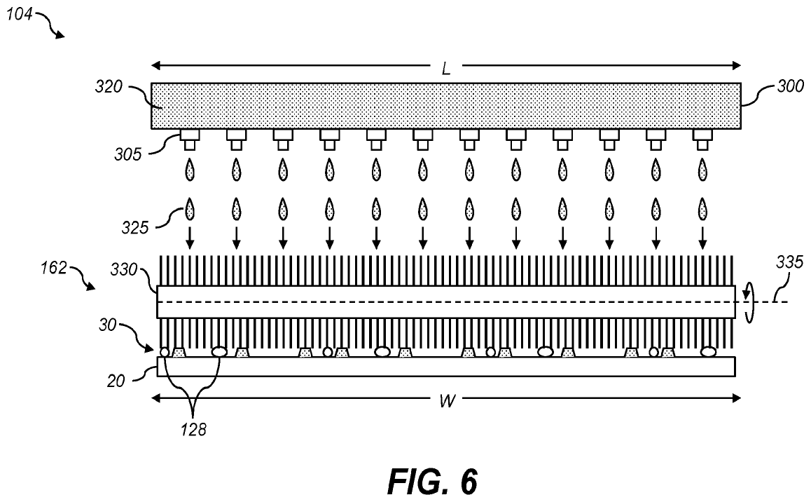

Additional details of the processing unit 104 of FIG. 5 are illustrated in FIG. 6. The hollow tube 300 has a length L which extends across a cross-track width W of the printing plate 20. A plurality of pressure-compensating emitters 305 are distributed along the length of the hollow tube 300. The total flow rate of the processing solution through the processing unit 104 will be controlled by the dripping rate associated with the pressure-compensating emitters 305 together with the total number of pressure-compensating emitters 305. The total flow rate will be substantially independent of the internal pressure within the hollow tube 300 over a wide range of operating pressures.

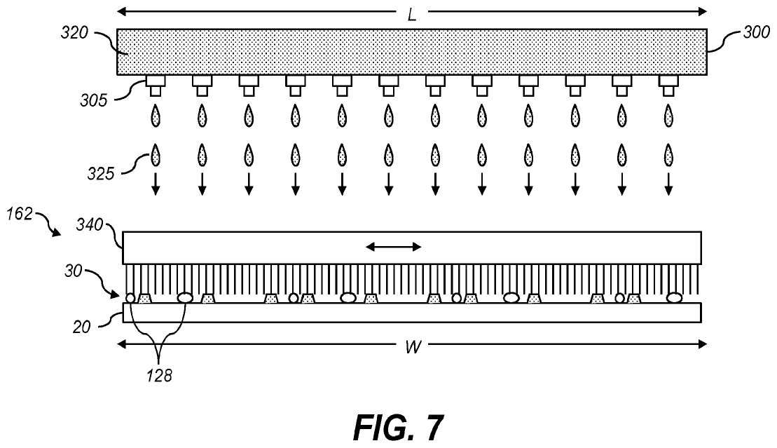

In the configuration of FIG. 6, the processing solution drips 325 impinge onto a rotating brush 330 which rotates around a rotation axis 335 parallel to the surface of the printing plate 20. The rotating brush 330 carries the processing solution onto the printing plate 20 and aids in the removal of the debris 128 from the relief image 30. FIG. 7 shows an alternate configuration which uses a brush 340 which is translated laterally relative to the surface of the printing plate 20 using an oscillating motion.

An advantage of the present invention is that the flow rate through each of the pressure-compensating emitters 305 will be substantially equal (e.g., to within 30%) so that the processing solution will be applied uniformly across the cross-track width of the processing plate 20. Furthermore, the uniformity of the flow rate will be independent of the levelness of the hollow tube 300.

Another advantage of the present invention is that a lower flow rate of the processing solution 152 can be used compared to the prior art configuration of FIG. 3 without compromising the plate quality. This is desirable because it reduces the amount of processing solution 152 that must be used and disposed of for each processing plate. For comparison purposes a Dantex DigiWash DW4835 system was fitted with a trough-based liquid distribution system similar to that shown in FIG. 3 where the trough 200 had 43 dripping holes 205. The lowest flow rate where an even dripping rate along the length of the trough 200 could be achieved was 7.5 liters/minute. This corresponds to a dripping rate of 0.175 liters/minute through each of the holes 205. The processing system was re-fitted with the pressure-compensating-emitter-based system of FIG. 5 where a total of 33 pressure-compensating emitters 305 were used. In this case it was found that the total flow rate could be reduced to 2.5 liters/minute while still maintaining uniform flow across the width of the printing plate 20. This corresponds to a dripping rate of 0.076 liter/minute through each of the pressure-compensating emitters 305 and represents a 66% reduction in the total amount of processing solution 152 that is required without compromising the plate quality. The prior art configurations are not capable of operating at high quality levels at these low flow rates (e.g., flow rates per hole of less than 0.1 liters/minute).

While the exemplary embodiments have been described relative to processing units 104 used to process a printing plate 20 using aqueous processing solutions 152 containing a dispersing agent, it will be obvious to one skilled in the art that the invention can also be used for other types of processing systems as well. For example, it can be used for processing system that utilize a solvent-based processing solution. It can also be used for a rinsing system 106 which rinses the printing plate 20 with water as described above. In one such embodiment, it was found that an improved rinsing system 106 using a pressure-compensating-emitter-based water supply system could achieve good results with a flow rate of 4.0 liters/minute whereas the prior art system required 10.0 liters/minute.

The invention has been described in detail with particular reference to certain preferred embodiments thereof, but it will be understood that variations and modifications can be effected within the spirit and scope of the invention.

### PARTS LIST

10 mask material
12 mask layer
14 substrate
16 radiation
18 mask image
20 printing plate
22 photopolymer layer
24 substrate
26 radiation
28 latent image
29 cross-linked polymer region
30 relief image
100 processing system
101 processing path
102 main processing unit
104 processing unit
105 processing solution removal system
106 rinsing unit
108 drying unit
110 platen
112 pump
113 pipe
114 pump
116 pump
124 exposed portions
126 unexposed portions
128 debris
140 processing solution tank
142 aqueous processing solution
143 used aqueous processing solution
144 collection system
146 conduit
148 filter
150 supply tank
152 processing solution
153 used secondary aqueous processing solution
154 collection system
156 conduit
160 mechanical cleaning system
162 mechanical cleaning system
170 water
172 air knife
180 holding tank
181 waste processing solution
182 coagulant supply system
184 coagulant
186 coagulated polymer
200 trough
205 hole
210 inlet
215 valve
300 hollow tube
305 pressure-compensating emitter
310 processing liquid supply system
315 pump
320 pressurized processing solution
325 processing solution drips
330 brush
335 axis
340 brush

1. A method for processing a photosensitive flexographic printing plate having a relief image of an aqueous-processable photopolymer, comprising:
providing a relief image into a processing unit that processes the flexographic printing plate with a processing liquid, the processing unit including:
a hollow tube having a length extending across the flexographic printing plate;
a pressurized processing liquid supply system for supplying pressurized processing liquid into an interior of the hollow tube; and
a plurality of pressure-compensating emitters distributed along the length of the tube which deliver processing liquid onto a surface of the flexographic printing plate, wherein the pressurized processing liquid flows from the interior of the hollow tube through each of the pressure-compensating emitters at a controlled flow rate, wherein each pressure-compensating emitter is configured to control flow rate of the pressurized processing liquid to produce processing liquid drips;
emitting the processing liquid drips from the plurality of pressure-compensating emitters; and
washing the relief image with the processing liquid from the processing liquid drips.

2. The method of claim 1, further comprising applying the processing liquid to one or more brushes which move relative to the surface of the flexographic printing plate, wherein the one or more brushes apply the processing liquid to the relief image.

3. The method of claim 2, wherein the one or more brushes are rotating brushes rotate around an axis parallel to the surface of the relief image.

4. The method of claim 2, wherein the one or more brushes are translated laterally relative to the surface of the flexographic printing plate.

5. The method of claim 1, wherein the flow rate of the processing liquid drips from each of the pressure-compensating emitters is equal to within 30% of one another.

6. The method of claim 1, wherein the flow rate of the processing liquid drips from each of the pressure-compensating emitters is less than 0.1 liters/minute.

7. The method of claim 1, wherein the processing liquid is an aqueous processing solution including a dispersing agent.

8. The method of claim 1, wherein the processing liquid includes a solvent.

9. The method of claim 1, wherein the processing liquid is water.

10. The method of claim 1, wherein the pressurized processing liquid supply system pressurizes the processing liquid to about 30-60 psi.

11. The method of claim 10, wherein the controlled flow rate is the processing liquid drips, wherein the processing liquid drips have a rate across the plurality of pressure-compensating emitters to be within 30% with respect to each other.

12. The method of claim 1, wherein the processing liquid drip rate is about 0.076 liter/minute per 33 pressure-compensating emitters.

13. The method of claim 1, the plurality of pressure-compensating emitters being 33 pressure-compensating emitters.

14. The method of claim 1, wherein the plurality of pressure-compensating emitters are configured such that the processing liquid drip rate is independent of the pressure of the pressurized processing liquid in the hollow tube.

15. The method of claim 1, further comprising:
providing the photosensitive flexographic printing plate having a latent image that has at least one exposed portion with hardened photopolymer and at least one unexposed portion with unhardened photopolymer;
contacting the latent image with a first aqueous processing solution including a first dispersing agent;
mechanically cleaning the latent image in the presence of the first aqueous processing solution;
removing a majority of unhardened photopolymer from the at least one exposed portion with the first aqueous processing solution to form a first used aqueous processing solution having the photopolymer and to form the relief image from the latent image.

16. The method of claim 15, further comprising:
washing the relief image with the processing liquid being a second aqueous processing solution including a second dispersing agent, the second aqueous processing solution being devoid of the photopolymer; and
removing additional unhardened photopolymer from the at least one unexposed portion with the second aqueous processing solution to form a second used aqueous processing solution having the photopolymer.

17. The method of claim 16, further comprising:
combining the first used aqueous processing solution with the second used aqueous processing solution to form a combined used aqueous processing solution;
maintaining the combined used aqueous processing solution below a set maximum volume; and
maintaining a concentration of the photopolymer in the combined used aqueous processing solution below a set maximum photopolymer concentration.

18. The method of claim 17, wherein a first latent image is contacted the first aqueous processing solution with or without the photopolymer.

19. The method of claim 18, wherein a subsequent latent image is contacted with the combined used aqueous processing solution as the first aqueous processing solution.

20. A method for processing a photosensitive flexographic printing plate having a latent image formed by image-wise exposure of an aqueous-processable photopolymer, comprising:
providing the photosensitive flexographic printing plate having the latent image that has at least one exposed portion with hardened photopolymer and at least one unexposed portion with unhardened photopolymer;
contacting the latent image with a first aqueous processing solution including a first dispersing agent;
mechanically cleaning the latent image in the presence of the first aqueous processing solution;
removing a majority of unhardened photopolymer from the at least one exposed portion with the first aqueous processing solution to form a first used aqueous processing solution having the photopolymer and to form a relief image from the latent image;
emitting droplets of a second aqueous processing solution from a plurality of pressure-compensating emitters;
washing the relief image with the second aqueous processing solution including a second dispersing agent, the second aqueous processing solution being devoid of the photopolymer;
removing additional unhardened photopolymer from the at least one unexposed portion with the second aqueous processing solution to form a second used aqueous processing solution having the photopolymer;
combining the first used aqueous processing solution with the second used aqueous processing solution to form a combined used aqueous processing solution;
maintaining the combined used aqueous processing solution below a set maximum volume; and
maintaining a concentration of the photopolymer in the combined used aqueous processing solution below a set maximum photopolymer concentration,
wherein a first latent image is contacted the first aqueous processing solution with or without the photopolymer; and
wherein a subsequent latent image is contacted with the combined used aqueous processing solution as the first aqueous processing solution.
